(19) United States
(12) Patent Application Publication
(10) Pub. No.: US 2009/0302375 A1
(43) Pub. Date: Dec. 10, 2009

(54) METHOD OF MANUFACTURING A SEMICONDUCTOR DEVICE AND DEVICE MANUFACTURED BY THE METHOD

(75) Inventors: Jan Sonsky, Leuven (BE); Wibo D. Van Nort, Wappingers Falls, NY (US); Rob Van Dalen, Bergeijk (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/374,567

(22) PCT Filed: Jul. 19, 2007
(86) PCT No.: PCT/IB07/52884

§ 371 Date: Jan. 22, 2009

(30) Foreign Application Priority Data
Jul. 24, 2006 (EP) 06117740.8
Jul. 19, 2007 (IB) PCT/IB2007/052884

(51) Int. Cl. H01L 29/78; H01L 21/336

(52) U.S. Cl. 257/329; 438/268; 257/E21.41; 257/E29.262

(57) ABSTRACT

A method of manufacturing a semiconductor device includes forming trenches (22), and then selectively etching a buried layer (14) to form a cavity. An insulator is then deposited on the sidewalls of the trenches (22), not covering the cavity, and the cavity is then used to form a conductive region (28) in the cavity. The trench (22) can then be filled with insulator (40), in which case the conductive region (28) may form a precisely located doped region, or with conductor to form a contact to the conductive region (28).

The invention relates to a method of manufacturing a semiconductor device using a trench with insulated sidewalls and cavities formed on the sidewalls, and a device manufactured with the method.

Insulated gate semiconductor devices (for example MOSFETs) with source, body, gate and drain, and heterojunction bipolar transistors (HBT) with emitter, base and collector are known in a large number of different configurations to meet a number of design goals. In the high voltage and power applications, there are two important goals in MOSFET design; the specific on-resistance, i.e. the resistance of the semiconductor per unit area with the device turned on, and the breakdown voltage, i.e. the voltage that can be resisted with the device turned off. There is generally a trade-off between these goals, such that increasing the doping to improve the on-resistance reduces the breakdown voltage. Furthermore the best trade-off should be accomplished with limited sensitivity to process variations. In order to improve these properties, a number of approaches use a low-doped drain region, often called a drift region, between the body and the drain region. The drift region is arranged to be depleted when the device is turned off but to pass current with the device turned on. A number of approaches to enhance depletion of the drift region are known, including for example doped regions of opposite conductivity type adjacent to the drift region.

However, the exact effect of this approach depends critically on the doping balance between the drift region and the compensating region of the opposite doping. Small variations from exact doping concentration balance (equality) leads to significant degradation of breakdown voltage. In order to achieve such doping balance, state-of-the-art manufacturing tools performing at their best are required. This may result in poor yield, process ruggedness issues etc. Also, the desired doping profile is often difficult to achieve using conventional techniques—for example the optimum doping profile in the drift region is often graded and it is difficult to achieve the exact doping profile simply by implanting dopants and diffusing them.

Accordingly there remains a need for an improved method of making MOSFETs for high voltage and power applications.

The HBTs using SiGe base are mainly used for high-frequency switching (larger than 50 GHz) at low voltages. In order to achieve such high-frequency operations, the parasitic capacitances and resistances must be reduced as much as possible. It is particularly important to provide a low resistance connection to base and collector with low parasitic capacitance. The HBTs are vertical transistors using a stack of a collector, a base and an emitter, wherein the base is a thin SiGe layer of opposite conductivity type (p−doped or n−doped) to the collector and emitter. A difficulty in this case is obtaining a good contact to the thin base layer. To ensure reliable and low-resistance contacting, the base layer may need to be manufactured to be thicker than would otherwise be ideal. Furthermore the connection of the intrinsic base region to the periphery, where the metal contacts are located, is realized through the SiGe base layer that has large resistance respective to resistance of metal connection. It is therefore highly preferred to realize metallic base connections as closely as possible to the intrinsic base location. Such connections have to be furthermore sufficiently isolated from the surroundings.

There thus remains a need for improved methods of making bipolar transistors in particularly in reducing resistance and capacitance of base connections.

According to the invention there is provided a method including:

depositing a plurality of layers of a first semiconductor material with at least one buried layer of a different second semiconductor material interspersed between the plurality of layers;

forming trenches through at least some of the plurality of layers including through at least one buried layer;

selectively etching part of the buried layer of second semiconductor material to form cavities where the trenches pass through the buried layers;

depositing insulator on the sidewalls of the trenches leaving the cavities exposed; and

forming conductive regions at the cavities.

The location of the conductive regions is determined by the depth of the buried layers of second semiconductor material. This can be controlled by epitaxy, a very exact process, so it is straightforward to arrange the conductive regions at precise depths.

In an embodiment, the method may be used in a MOSFET structure with the first region a high-doped drain layer, and the second region a low-doped drain region doped to be the first conductivity type but to a lower doping concentration than the high-doped drain layer. The method may include:

forming a body region of a second semiconductor type opposite to the first semiconductor type;

forming a source region of the first semiconductor type; and

forming an insulated gate to control conduction from the source region through the body region to the low-doped drain region.

The step of forming conductive regions in the cavities may include vapour phase doping the cavities to form doped regions on the sidewalls of the cavities.

The trench may be filled with insulating material after vapour phase doping the cavities.

In a different embodiment, the plurality of layers may include a buried collector region of first conductivity type and first semiconductor material, a base layer of second conductivity type opposite to the first conductivity type and second semiconductor material and an emitter region of first conductivity type and first semiconductor material above the base layer. The step of forming conductive regions in the cavities may include filling at least one of the trenches with conductor to connect to the base layer; and the method may further include forming an emitter region of first conductivity type and first semiconductor material above the base layer.

The trenches may include collector trenches and base trenches, the method further including:

forming the at least one buried layer to be patterned to include base connecting regions where the at least one buried layer is present and collector connecting regions where the at least one buried layer is absent;

forming the trenches to include collector trenches passing through the collector connecting regions and base trenches passing through the base connecting regions, the collector trenches extending to the collector region;

after depositing insulator on the sidewalls and base of the trenches, etching the insulator away from the base of the collector trenches but not the base trenches so that the step of filling the trenches with conductor connects the filling in the collector trenches to the collector and the filling in the base trenches to the base.

The first semiconductor material may be silicon and the second semiconductor material silicon-germanium.

In another aspect, the invention relates to a semiconductor device comprising:

a plurality of layers of a first semiconductor material with at least one buried layer of a different second semiconductor material interspersed between the plurality of layers;

trenches extending through at least some of the plurality of layers including through at least one buried layer;

a plurality of doped conductive regions where the trenches pass through the buried layers; and

insulator on the sidewalls of the trenches except adjacent to the conductive regions.

For a better understanding of the invention, embodiments will now be described, purely by way of example, with reference to the accompanying drawings in which:

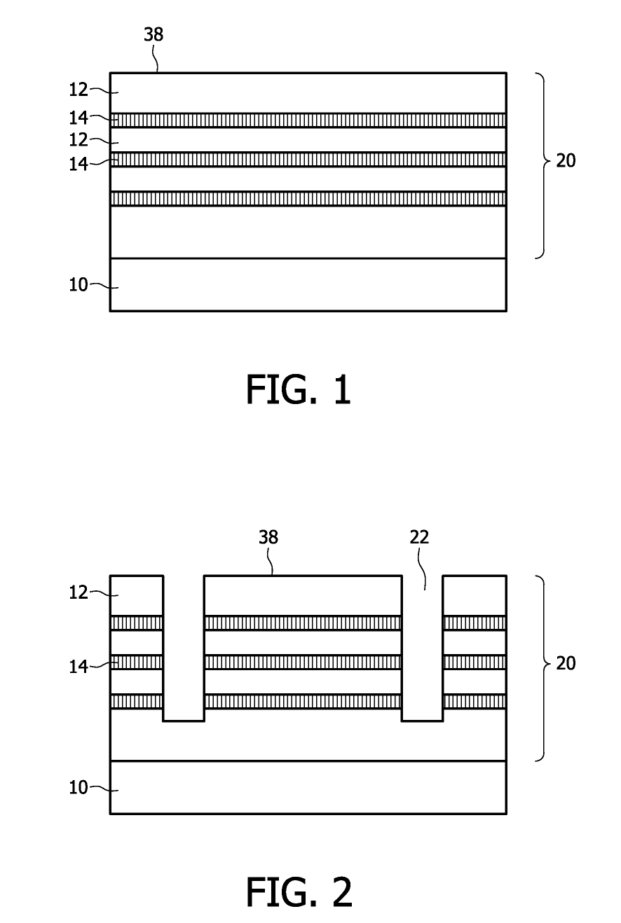

FIGS. 1 to 5 show steps of a method according to the invention in side view;

FIG. 6 shows in side view a device made as illustrated in FIGS. 1 to 5; and

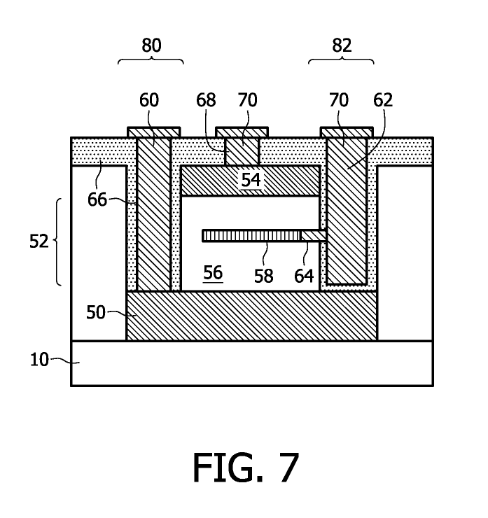

FIG. 7 shows a device according to another embodiment of the invention.

Like or corresponding components are given the same reference numerals in the different figures. The drawings are not to scale and the vertical direction in particular is expanded for greater clarity. Insulating regions are shown with a dot pattern, SiGe regions are shown with vertical lines and metallisation layers with strong oblique lines.

A first embodiment of a method of manufacturing a semiconductor device according to the invention will now be described with reference to FIGS. 1 to 6. The first embodiment relates to manufacturing a MOSFET and the MOSFET thus manufactured.

To manufacture the MOSFET, firstly a n+substrate 10 is provided as a drain region. Then, a plurality of low-doped n−type layers 12 of Si and buried layers 14 of SiGe are deposited, alternating to provide a top layer of Si 12 at the first major surface 38 to provide a low doped drain region 20, arriving at the arrangement of FIG. 1. In the embodiment, the SiGe layers 14 contain 25% Ge and are 20 nm thick.

Deep access trenches 22 are then formed extending through the low doped drain region 20 past all the buried SiGe layers 14. Although the depth of the trenches is not critical, the deep access trenches 22 in this embodiment do not extend as far as drain 10, as shown in FIG. 2.

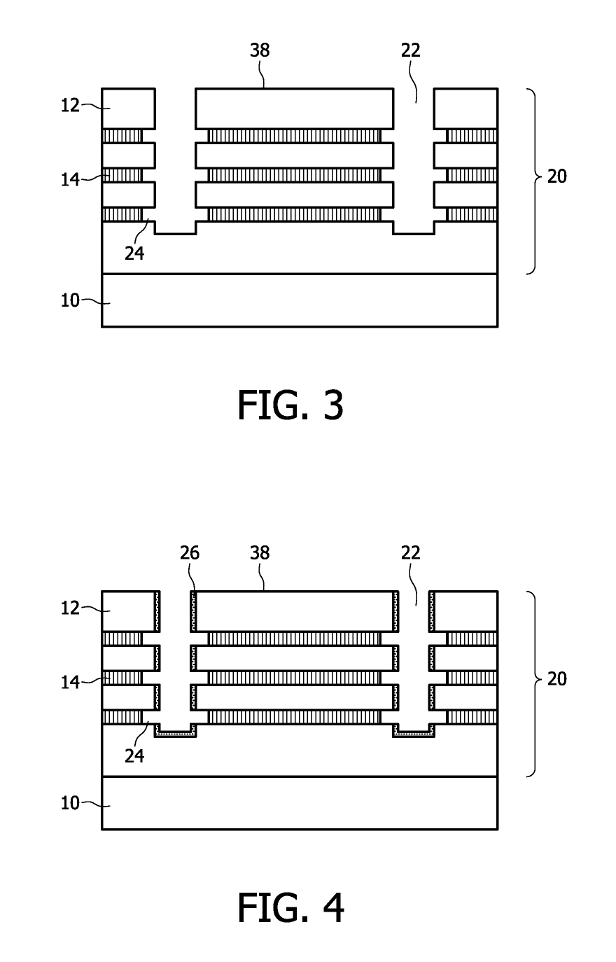

Small cavities 24 are then formed adjacent to the trenches 22 at the SiGe layers using a selective etch that preferentially etches SiGe compared to Si. The resulting structure is illustrated in FIG. 3.

A protective layer 26 is then formed on the sidewalls of the trenches as illlustrated in FIG. 4. This is carried out using a process with poor step coverage so that the protective layer does not fill the cavities 24.

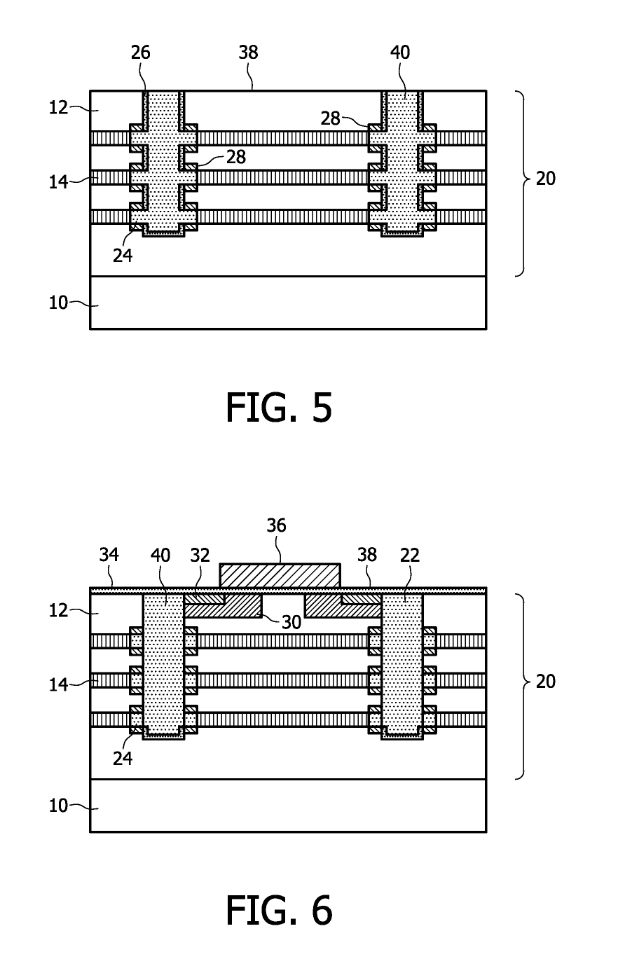

A vapour phase doping step is then used to heavily dope the sidewalls of the cavities 24 creating conductive regions 28 as shown in FIG. 5.

Following this the trenches 22 and cavities 24 are filled with insulator 40.

A body diffusion to form body region 30 is followed by gate insulator 34 growth or deposition across the first major surface 38 and gate 36 deposited and patterned, following which a source region 32 is implanted or diffused, to arrive at the device of FIG. 6. Although not shown, a heavily doped body contact implant may be provided next to the source to guarantee a good connection to the body, as is known in the art.

The resulting device is illustrated in FIG. 6. The device is a vertical MOSFET with an n+source region 32, p−type body region 30, n−type low doped drain region 20, also known as a drift region and n+drain region 10.

Trenches 22 filled with insulator 40 extend vertically through the low doped drain region 20 and floating sidewall doping regions 28 doped p++ are provided adjacent to the trenches 22. The body regions 30 are provided adjacent to the trenches 22 at first major surface 38 and the source regions 32 are provided within the body regions 30 adjacent to the trenches 22 at the first major surface 38, the source regions 32 being narrower and shallower than the body regions 30 so that the body regions 30 extend under the source regions 32. The body regions 30 do not extend inwards from the trenches 22 as far as a central region 42 at the first major surface 38 between adjacent trenches 22, the central region 42 thereby forming part of low doped drain region 20 and to provide current path from the gate channel.

A conductive gate 36 extends on the top of gate insulator 34 above the first major surface 38 between the source region 32 and central region 42 over the body region 30 for forming a channel through the body region 30.

The spacing of the conductive regions 28, which may also be referred to as sidewall doping regions, can be very accurately controlled indeed since it is determined by the thickness of the Si and SiGe layers 12,14 which are determined by the epitaxial growth process, a very accurate process. This in turn results in an accurate potential distribution across the low doped drain region 20. The device does not operate using charge balance between the n−doping in the drift region 12 and p+doping regions 28 in the cavity sidewalls. Instead the floating p+regions 28 will pick potential through reach-through current, which occurs during reverse biasing of the drain, resulting in a substantially linear potential distribution along the drift region.

A further application of the techniques discussed above is provided in FIG. 7. In this embodiment, the trenches are used to connect to buried layers in a bipolar structure.

Referring to FIG. 7, a vertical bipolar transistor structure has a substrate 10 for example a lowly doped p−substrate. A doped collector layer 50 is provided on the substrate, a base layer 52 above the collector layer 50 and an emitter layer 54 above the base layer 52. The collector layer 50, base layer 52 and emitter layer 54 thus correspond to a second region 20, having a corresponding structure, though not function, as the second region 20 of the first embodiment. The collector layer 50 and emitter layer 54 are both heavily doped n−type, and the base layer 52 is a p−type doped SiGe layer.

The SiGe base layer 52 may be patterned such that it does not extend across the full width of the transistor structure. It is present in base connecting region 82 but absent from collector connecting region 80.

The transistor is made by depositing the layers as set out above, and then forming contacts to the layers. This is done by forming a collector trench 60 and a base trench 62. These both extend to the collector layer 50, and may conveniently be formed together. The trenches 60, 62 and SiGe base layer 52 are patterned so that the base trench 62 extends through the SiGe base layer 52 in base connecting region 82 and the collector trench 60 extends through the level of the SiGe base layer 52 at collector connecting region 80. Since the SiGe base layer 52 is not present here the collector trench 60 does not contact the SiGe base layer 52.

Then, a short selective etch is carried out to etch the SiGe base layer 52 where it is exposed at the sidewalls of the base trench 62. This creates cavity 64. Next, an insulating layer 66 is deposited on the sidewalls and base of the trenches, as well as on the top of the device. As in the embodiment of FIGS. 1 to 6, a process is used that does not fill the cavity 64. Then, the insulating layer is removed from the bottom of the collector trench 60 and not the base trench 62 by a masked etch process. In the embodiment, the same step is also used to etch insulating layer 66 above the emitter layer 54 to form an emitter via 68 at the top of the emitter layer 54.

A metallisation 70 is then used to fill the base trench 62, collector trench 60 and emitter via 68 together with the cavity 64 in communication with base trench 62. The metallisation filling cavity 64 forms connecting region 65. The metallisation 70 in the collector trench 60 is in contact with the collector layer 50, the metallisation in the base trench is in contact with the base layer 52 through the connecting region 65 in filled cavity 64, and the metallisation 70 in the emitter via 68 is in contact with the emitter layer 54. In this way, contacts are conveniently made to the collector, emitter and base.

This method can be used to form a very accurately aligned contact to the base layer 52 which is in general a difficult problem since the base layer 52 is normally very thin.

In a variation, the collector region 50 may also include a SiGe layer, doped to be of opposite conductivity type to the base layer. This is a favorable case, since the metal comes close to the intrinsic part of the transistor and thus reduces the resistance of the doped silicon connection. In this case, the SiGe layers forming the base layer 52 and part of the collector region need not be patterned.

The embodiments above are provided purely by way of example and those skilled in the art will realise that many variations are possible.

The type of transistors and devices formed is not limited in any way.

In particular, as well as the transistor of FIG. 7, the base contacting method is equally applicable to a more conventional heterostructure bipolar transistor with the collector contact to the implanted region not through a collector trench but using a conventional contact to the doped collector layer or substrate.

For example, it is not necessary to use Si for the device layer and the substrate and SiGe for the buried layer. Any semiconductors may be used, as long as a suitable selective etch for the material of the buried layer is available. The vapor phase doping method is an example of method that can be used to form the cavity sidewall doping, but other methods for doping of non-conformal surfaces, e.g. immersion plasma doping, can be used.

The first embodiment of the method is particularly, but not exclusively, suitable for high power or high voltage applications. The second embodiment of the method is particularly suitable for heterojunction bipolar transistors for fast switching applications.

Note that although the embodiments described include an embodiment connecting to a buried layer in a bipolar transistor and floating regions in a low-doped drain region in a insulated gate transistor, this is not essential, and it is also possible, for example, to use the method to provide the floating regions in a region of a bipolar transistor structure for a high voltage applications. P-channel and N-channel can be made as well as PNP and NPN bipolar transistors.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The applicant hereby gives notice that new claims may be formulated to such features and/or combinations of such features during the prosecution of the present application or of any further application derived therefrom.

1. A method of manufacturing a semiconductor device comprising:
depositing a plurality of layers of a first semiconductor material with at least one buried layer of a different second semiconductor material interspersed between the plurality of layers;
forming trenches through at least some of the plurality of layers including through at least one buried layer;
selectively etching part of the buried layer of second semiconductor material to form cavities where the trenches pass through the buried layers;
depositing insulator on the sidewalls of the trenches leaving the cavities exposed; and
forming conductive regions at the cavities.

2. A method according to claim 1 wherein the method includes:
providing a first region for forming a high-doped drain layer, the first region being of the first semiconductor material and doped to be a first conductivity type;
wherein the step of depositing a plurality of layers of a first semiconductor material with at least one buried layer of a different second semiconductor material forms a low doped drain region doped to be the first conductivity type but to a lower doping concentration than the high-doped drain layer;
the method further comprising:
forming a body region of a second semiconductor type opposite to the first semiconductor type;
forming a source region of the first semiconductor type; and
forming an insulated gate to control conduction from the source region through the body region to the low-doped drain region.

3. A method a to claim 1 wherein the step of forming conductive regions at the cavities includes vapour phase doping the cavities to form doped regions on the sidewalls of the cavities.

4. A method according to claim 3 further comprising filling the trench with insulating material after vapour phase doping the cavities.

5. A method according to claim 1 wherein the step of depositing a plurality of layers of a first semiconductor material with at least one buried layer of a different second semiconductor material includes depositing a buried collector region of first conductivity type, a base layer of second conductivity type opposite to the first conductivity type and of the different second semiconductor material and an emitter region of first conductivity type above the base layer;
wherein forming conductive regions in the cavities includes filling at least one of the trenches with conductor to fill the at least one trench and the cavities to connect to the base layer.

6. A method according to claim 5 wherein the trenches include collector trenches and base trenches, the method further including:
forming a buried base layer patterned to be present in a base connecting region but not in a collector connecting region;
forming the trenches to include collector trenches passing through the collector connecting region and base trenches passing through the base connecting region, the collector trenches extending to the collector region;
after depositing insulator on the sidewalls and base of the trenches, etching the insulator away from the bottom of the collector trenches but not the base trenches so that the step of filling at least one of the trenches with conductor connects the conductor in the collector trenches to the collector and the conductor in the base trenches to the base.

7. A method according t claim 1, wherein the first semiconductor material is silicon and the second semiconductor material is silcon-germanium.

8. A semiconductor device, comprising:
a plurality of layers of a first semiconductor material with at least one buried layer of a different second semiconductor material interspersed between the plurality of layers;
trenches extending through at least some of the plurality of layers including through at least one buried layer;
a plurality of conductive regions where the trenches pass through the buried layers; and
insulator on the sidewalls of the trenches except adjacent to the conductive regions.

9. A semiconductor device according to claim 8, further comprising:
a high-doped drain layer;
wherein the plurality of layers of a first semiconductor material with at least one buried layer of a different second semiconductor material form a low-doped drain region doped to be the first conductivity type but to a lower doping concentration than the high-doped drain layer; the device further comprising:
a body region of a second semiconductor type opposite to the first semiconductor type;
a source region of the first semiconductor type; and
an insulated gate to control conduction from the source region through the body region to the low-doped drain region.

10. A semiconductor device according to claim 8, wherein:
the plurality of layers of a first semiconductor material with at least one buried layer of a different second semiconductor material forms include:
a buried collector region of first conductivity type;
a base layer of second conductivity type opposite to the first conductivity type and of different second semiconductor material; and
an emitter region of first conductivity type above the base layer;
wherein at least one of the trenches is filled with conductor to connect to the base layer through the conductive regions.

11. A semiconductor device according to claim 10, wherein the trenches include collector trenches and base trenches, the collector trenches being connected to the collector region and the base trenches being connected to the base layer through the conductive regions.

12. A semiconductor device according to claim 8, wherein the first semiconductor material is Si and the second semiconductor material is SiGe.
